(19) United States
(12) Patent Application Publication
(10) Pub. No.: US 2012/0227942 A1
(43) Pub. Date: Sep. 13, 2012

(54) FLOW GUIDE STRUCTURE AND THERMAL MODULE THEREOF

(75) Inventors: Fu-Jung Wu, New Taipei City (TW); Chien-Yen Lu, New Taipei City (TW)

(73) Assignee: ASIA VITAL COMPONENTS CO., LTD., New Taipei City (TW)

(21) Appl. No.: 13/045,532

(22) Filed: Mar. 11, 2011

(51) Int. Cl. H01L 23/467; F03B 11/02

(52) U.S. Cl. 165/121; 137/561 R

(57) ABSTRACT

A flow guide structure includes a support body including a hollow frame body. At least one first flow way and at least one flow guide assembly are disposed in the hollow frame body. The flow guide assembly has multiple flow guide plates arranged at intervals. At least one second flow way is formed between the flow guide plates. When a cooling fan creates airflow and blows the airflow to a heat sink and a circuit board, the flow guide plates of the flow guide assembly can also guide the airflow to those areas with high heat so as to lower the temperature of the electronic components in the areas.

### FIELD OF THE INVENTION

The present invention relates to a flow guide structure, and more particularly to a flow guide structure and a thermal module thereof. The flow guide structure is able to control the direction of the airflow and guide the airflow to the electronic components with higher heat so as to lower the temperature of the electronic components.

### BACKGROUND OF THE INVENTION

Recently, following the rapid advance of the electronic information technique, various electronic products (such as computers and notebooks) have been more and more popularly used. As exemplified by a computer, there is a trend to enhance the processing speed of the central processing unit (CPU) of the computer and increase the access capacity of the CPU. Under such circumstance, the CPU will generate heat at higher and higher power.

The electronic product is generally equipped with a thermal module for helping in dissipating the heat generated by the electronic components of the electronic product. Otherwise, the temperature of the electronic components will rise very quickly to cause deterioration of the execution efficiency or even burnout of the electronic components. FIG. 1 shows a conventional thermal module assembly, which includes a thermal module 13, a cooling fan 12 and a support structure 10. The support structure 10 has a support body 11 having an upper end face 111. The cooling fan 12 is mounted on the upper end face 111. A lower end of the support body 11 has a cap section 112 capped on a first side of the thermal module 13. A second side of the thermal module 13 is attached to a heat source (central processor) of a motherboard 14. The thermal module 13 serves to absorb the heat generated by the heat source of the motherboard 14. The cooling fan 12 on the first side serves to create airflow to dissipate the heat from the thermal module 13 and the motherboard 14. The support structure 10 is simply used to connect the cooling fan 12 to the thermal module 13 without any flow guide design. Therefore, the airflow created by the cooling fan 12 will only dissipate the heat of the thermal module 13 under the cooling fan 12, while failing to also dissipate the heat of the electronic components on the other areas of the motherboard 14. As a result, the operation efficiency of the motherboard 14 will be affected.

According to the above, the conventional support structure has the following shortcomings:
1. The airflow created by the cooling fan is not fully utilized.
2. The heat generated by the electronic components cannot be effectively dissipated.
3. The operation efficiency of the motherboard is affected.

### SUMMARY OF THE INVENTION

A primary object of the present invention is to provide a flow guide structure and a thermal module thereof. The flow guide structure is able to control the direction of the airflow.

A further object of the present invention is to provide the above flow guide structure and the thermal module thereof. When a cooling fan creates airflow and blows the airflow to a heat sink and a circuit board, the flow guide structure can also guide the airflow to the electronic components with higher heat so as to lower the temperature of the electronic components.

To achieve the above and other objects, the flow guide structure of the present invention includes a support body including a hollow frame body. At least one first flow way and at least one flow guide assembly are disposed in the hollow frame body. The first flow way is not overlapped with the flow guide assembly. The flow guide assembly has multiple flow guide plates arranged at intervals. At least one second flow way is formed between the flow guide plates. When a cooling fan creates airflow and blows the airflow to a heat sink and a circuit board, the flow guide plates of the flow guide assembly can control and guide the airflow to the other areas with high heat so as to lower the temperature of the electronic components in the areas.

To achieve the above and other objects, the thermal module of the present invention includes a cooling fan, a support body and a heat sink. The support body has a first side and a second side. The cooling fan is assembled with the first side of the support body, while the heat sink is assembled with the second side of the support body. The support body includes a hollow frame body in which at least one first flow way and at least one flow guide assembly are disposed. The first flow way is not overlapped with the flow guide assembly. The flow guide assembly has multiple flow guide plates arranged at intervals. At least one second flow way is formed between the flow guide plates. When the cooling fan creates airflow and blows the airflow to the heat sink and the circuit board, the flow guide plates of the flow guide assembly can control and guide the airflow to the other areas with high heat so as to lower the temperature of the electronic components in the areas.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view showing a support structure of a conventional thermal module;

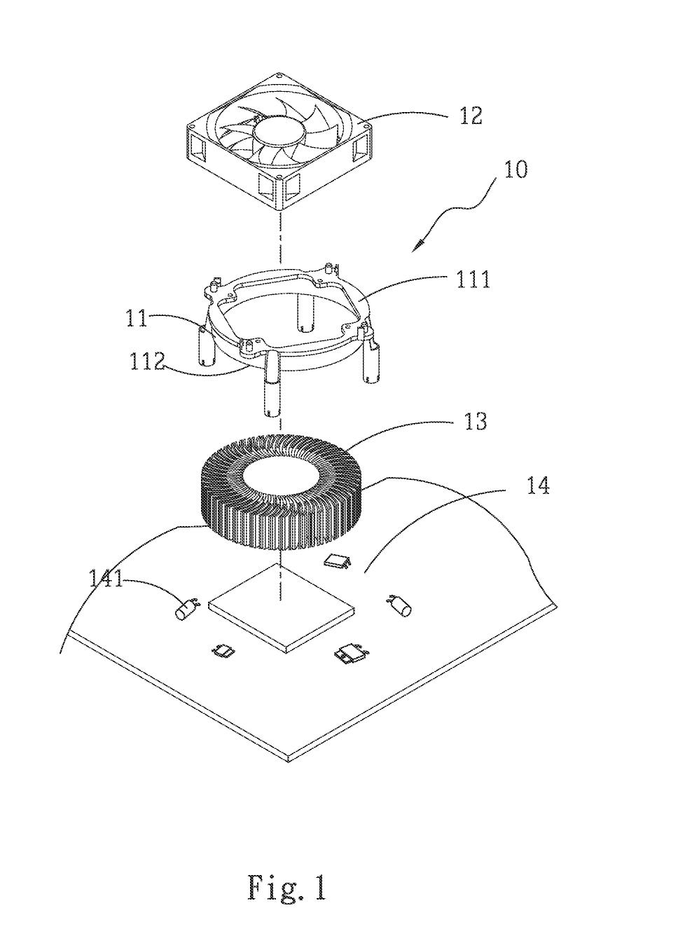

FIG. 2 is a perspective assembled view of a first preferred embodiment of the flow guide structure of the present invention;

FIG. 3 is a perspective exploded view of a second preferred embodiment of the flow guide structure of the present invention;

FIG. 4A is a perspective exploded view of a first preferred embodiment of the thermal module of the present invention;

FIG. 4B is a perspective assembled view of the first preferred embodiment of the thermal module of the present invention;

FIG. 4C is a sectional assembled view of the first preferred embodiment of the thermal module of the present invention;

FIG. 5 is a perspective exploded view of a second preferred embodiment of the thermal module of the present invention; and

FIG. 6 is a perspective assembled view of the second preferred embodiment of the thermal module of the present invention.

### DETAILED DESCRIPTION OF THE PREFERRED EMBODIMENTS

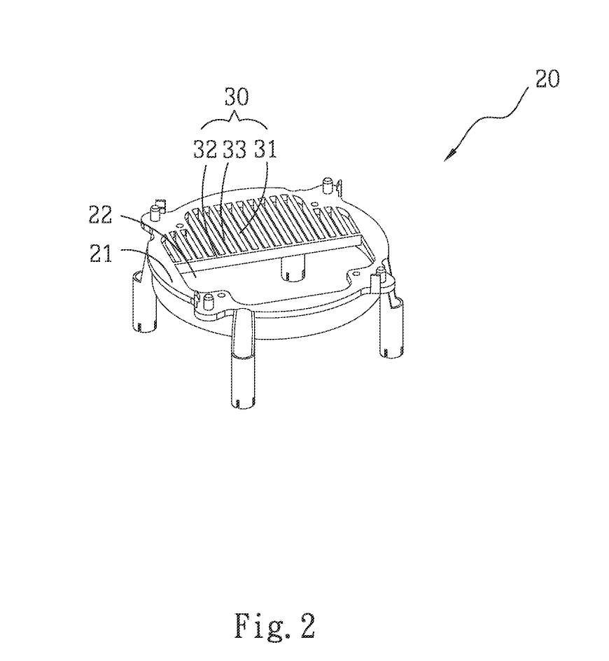

Please refer to FIG. 2, which is a perspective assembled view of a first preferred embodiment of the flow guide structure of the present invention. The flow guide structure includes a support body 20 including a hollow frame body 21. At least one first flow way 22 and at least one flow guide assembly 30 are disposed in the hollow frame body 21. In this embodiment, there is one flow guide assembly 30 integrally formed in the hollow frame body 21. The first flow way 22 is not overlapped with the flow guide assembly 30. The flow guide assembly 30 has multiple flow guide plates 31 and at least one border 32. The flow guide plates 31 are arranged at intervals and connected to the border 32. In addition, multiple second flow ways 33 are formed between the flow guide plates 31 and the border 32. The second flow ways 33 are inclined from the support body 20 by an inclination angle.

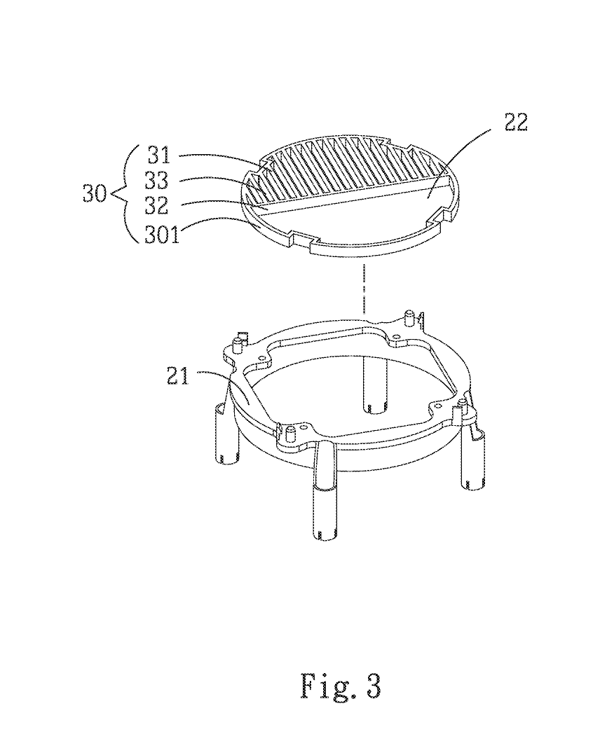

FIG. 3 is a perspective exploded view of a second preferred embodiment of the flow guide structure of the present invention. The components of the second embodiment are substantially identical to those of the first embodiment in connection relationship and operation and thus will not be repeatedly described hereinafter. The same components are denoted with the same reference numerals. The second embodiment is different from the first embodiment in that the flow guide assembly 30 has an outer rim 301. The flow guide assembly 30 is assembled in the hollow frame body 21 via the outer rim 301. The outer rim 301 has a size adapted to that of the hollow frame body 21. The first flow way 22 of the hollow frame body 21 is formed inside the outer rim 301. In addition, the first flow way 22 is partitioned from the second flow ways 33 of the flow guide plates 31 by the border 32.

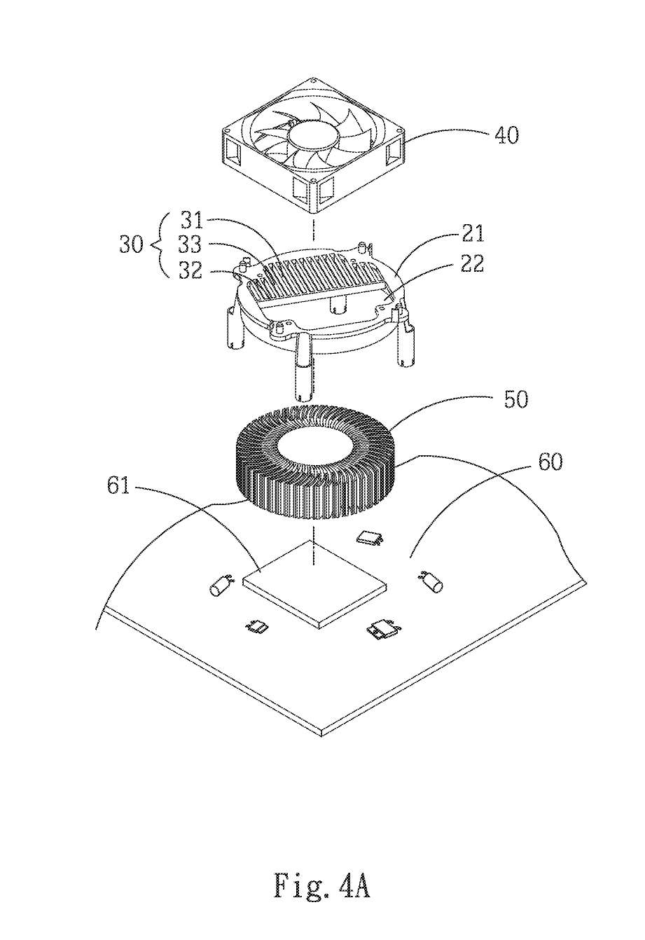

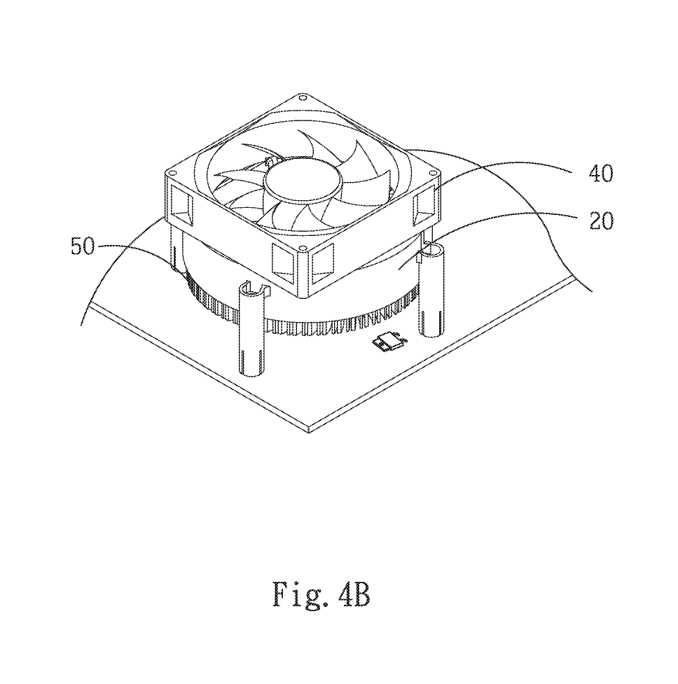

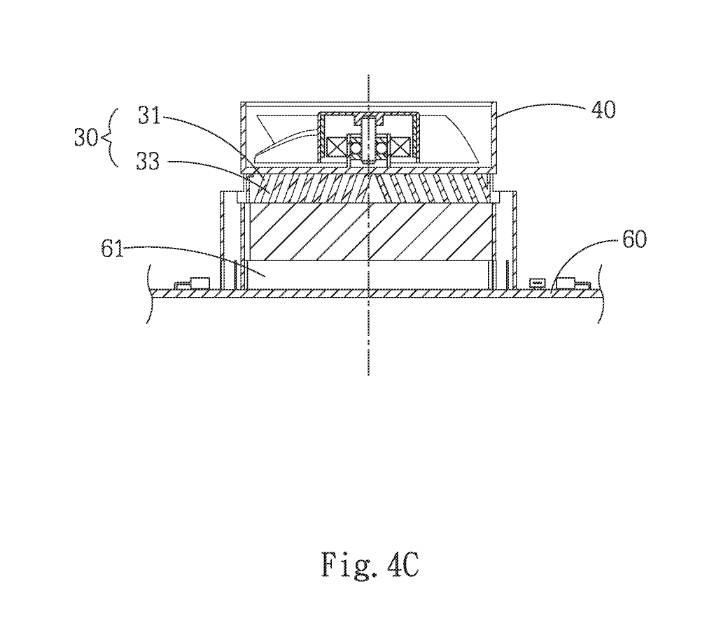

Please now refer to FIGS. 4A, 4B and 4C, in which FIG. 4A is a perspective exploded view of a preferred embodiment of the thermal module of the present invention, FIG. 4B is a perspective assembled view of the preferred embodiment of the thermal module of the present invention, while FIG. 4C is a sectional assembled thereof. The thermal module includes a cooling fan 40, a support body 20 and a heat sink 50. The cooling fan 40 is assembled with a first side of the support body 20. The heat sink 50 is assembled with a second side of the support body 20 and attached to a motherboard 60 with a central processor. The support body 20 includes a hollow frame body 21 in which at least one first flow way 22 and at least one flow guide assembly 30 are disposed.

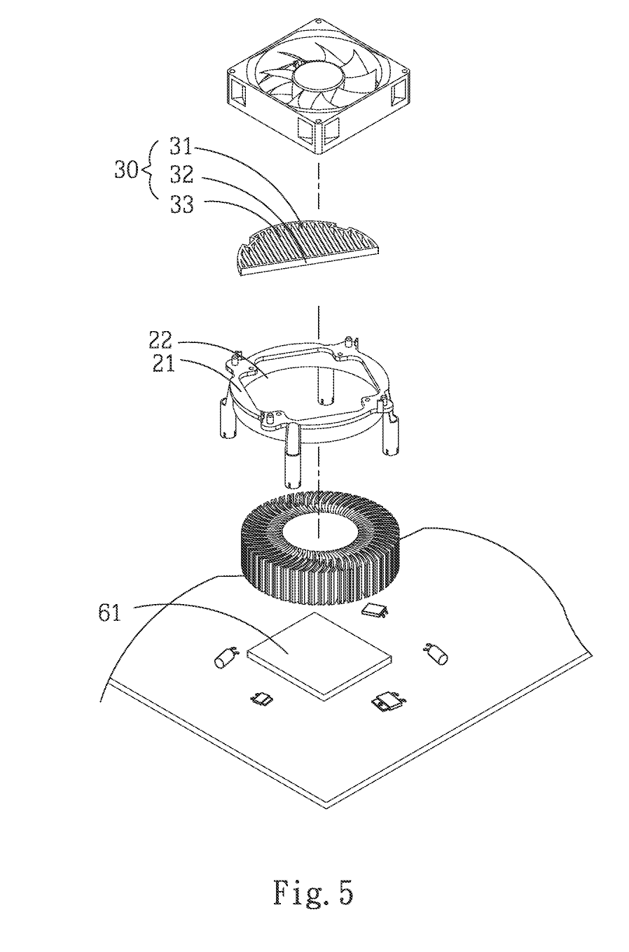

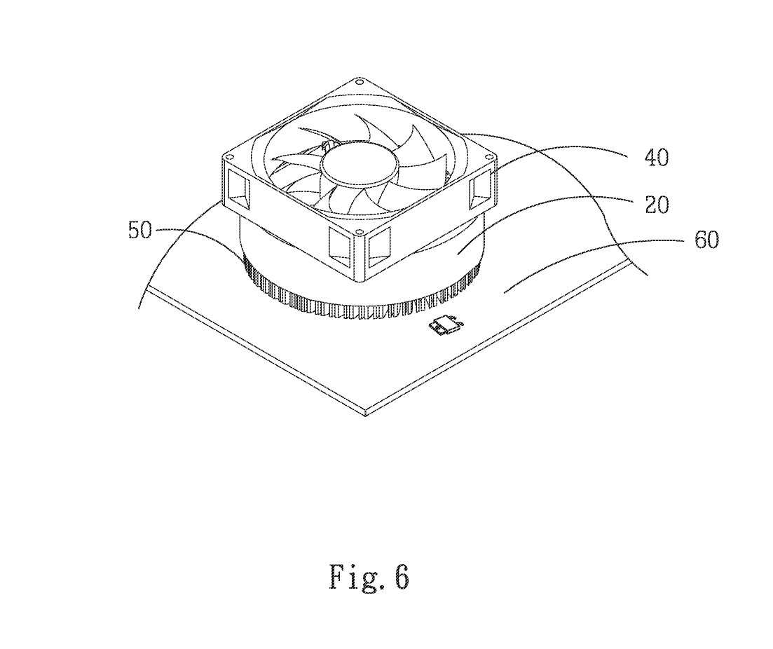

The hollow frame body 21 and the flow guide assembly 30 can be integrally formed. Alternatively, the flow guide assembly 30 is detachably assembled in the hollow frame body 21 according to the positional relationship between the cooling fan 40, the support body 20, the heat sink 50 and the motherboard 60 (as shown in FIGS. 5 and 6). In this embodiment, the hollow frame body 21 and the flow guide assembly 30 are integrally formed.

The first flow way 22 is not overlapped with the flow guide assembly 30. The flow guide assembly 30 has multiple flow guide plates 31 and at least one border 32. The flow guide plates 31 are arranged at intervals and connected to the border 32. In addition, multiple second flow ways 33 are formed between the flow guide plates 31 and the border 32. The second flow ways 33 are inclined from the support body 20 by an inclination angle. Multiple electronic components are disposed on the motherboard 60. In operation, the electronic components of the motherboard 60 will generate different amounts of heat. Therefore, the support body 20 is assembled with the motherboard 60 in a relative position according to the positions of the laid out electronic components. The flow guide plates 31 of the flow guide assembly 30 are directed to those electronic components that will generate high heat, (such as south and north bridge chips or other capacitor components or resistor components). The inclination angle of the flow guide plates is determined according to the positions of the objects to be heat-dissipated. Accordingly, the airflow created by the cooling fan 40 can pass through the flow guide assembly 30 and the first flow way 22 to the heat sink 50. In addition, the second flow ways 33 between the flow guide plates 31 can at the same time control and guide the airflow to those areas with higher heat so as to lower the temperature of the electronic components in the areas.

In conclusion, the flow guide structure and the thermal module thereof of the present invention have the following advantages:

1. The airflow can be guided to the electronic components with high heat.
2. The temperature of the electronic components can be effectively lowered.
3. The airflow of the cooling fan can be fully utilized.
4. The operation efficiency of the motherboard can be maintained.

The above embodiments are only used to illustrate the present invention, not intended to limit the scope thereof. It is understood that many changes and modifications of the above embodiments can be made without departing from the spirit of the present invention. The scope of the present invention is limited only by the appended claims.

What is claimed is:

1. A flow guide structure comprising a support body including a hollow frame body, at least one first flow way and at least one flow guide assembly being disposed in the hollow frame body, the first flow way being not overlapped with the flow guide assembly, the flow guide assembly having multiple flow guide plates arranged at intervals, multiple second flow ways being respectively formed between the flow guide plates.

2. The flow guide structure as claimed in claim 1, wherein the flow guide assembly further has at least one border, the flow guide plates being arranged along the border.

3. The flow guide structure as claimed in claim 2, wherein the flow guide plates are connected to the border to form the second flow ways.

4. The flow guide structure as claimed in claim 1, wherein the flow guide assembly is integrally formed in the hollow frame body.

5. The flow guide structure as claimed in claim 1, wherein the flow guide assembly further has an outer rim, the flow guide assembly being assembled in the hollow frame body via the outer rim.

6. The flow guide structure as claimed in claim 1, wherein a cooling fan is assembled with a first side of the support body and a heat sink is assembled with a second side of the support body.

7. The flow guide structure as claimed in claim 1, wherein the flow guide plates are inclined from the support body by an inclination angle.

8. A thermal module comprising:
a cooling fan;
a support body having a first side and a second side opposite to the first side, the support body including a hollow frame body in which at least one first flow way and at least one flow guide assembly are disposed, the first flow way being not overlapped with the flow guide assembly, the flow guide assembly having multiple flow guide plates arranged at intervals, multiple second flow ways being respectively formed between the flow guide plates; and
a heat sink assembled with the second side of the support body.

9. The thermal module as claimed in claim 8, wherein the flow guide assembly further has at least one border, the flow guide plates being arranged along the border.

10. The thermal module as claimed in claim 9, wherein the flow guide plates are connected to the border to form the second flow ways.

11. The thermal module as claimed in claim 8, wherein the flow guide assembly is integrally formed in the hollow frame body.

12. The thermal module as claimed in claim 8, wherein the flow guide assembly further has an outer rim, the flow guide assembly being assembled in the hollow frame body via the outer rim.

13. The flow guide structure as claimed in claim 8, wherein the flow guide plates are inclined from the support body by an inclination angle.
